(19) United States
(12) Patent Application Publication
(10) Pub. No.: US 2025/0051927 A1
(43) Pub. Date: Feb. 13, 2025

(54) Method of Metallization by a Nickel or Cobalt Alloy for the Manufacture of Semiconductor Devices

(71) Applicant: MacDermid Enthone Inc., Waterbury, CT (US)

(72) Inventors: Mikailou THIAM, L'Hay-les-Roses (FR); Hermine Marie BERTHON, Bretigny Sur Orge (FR); Amine LAKHDARI, Montreuil (FR)

(21) Appl. No.: 18/717,636

(22) PCT Filed: Feb. 7, 2023
(86) PCT No.: PCT/US2023/012471

§ 371 Date: Jun. 7, 2024

Related U.S. Application Data
(60) Provisional application No. 63/307,234, filed on Feb. 7, 2022.

(51) Int. Cl. C23C 18/50; C23C 18/16; C23C 18/18; C23C 18/36; H01L 21/48; H01L 25/065; H01L 27/06

(52) U.S. Cl. CPC C23C 18/50; C23C 18/1692; C23C 18/1844; C23C 18/36; H01L 21/4846; H01L 25/0652; H01L 27/0688

(57) ABSTRACT

A method of metallizing a semiconductor for the manufacture of three-dimensional semiconductor devices such as integrated circuits or storage memories. The metallization process includes a step of activating the surface, of a mineral oxide substrate with a noble metal, such as palladium, followed by a step of depositing a nickel or cobalt alloy containing boron and at least one of phosphorus and tungsten by electroless deposition.

### FIELD OF THE INVENTION

The present invention relates to the field of semiconductors, including three-dimensional devices such as dynamic random access memory (DRAM), integrated circuits, and three-dimensional vertical NAND storage memories (3D-NAND).

### BACKGROUND OF THE INVENTION

Dynamic random access memories consist of a transistor cell and a capacitor that are based on metal-oxide-semiconductor (MOS) technology. Capacitors are usually MIM (Metal-Insulator-Metal) capacitors composed of two U-shaped electrodes, an upper electrode and a lower electrode, separated by a dielectric material. The electrodes are based on metal oxides (i.e., RuO₂ and SrRuO₃, SnO₂ and MoO2) or metal (i.e., Pt, TiN, TaN, Ru—Pt, SnO₂ doped Ta). The dielectric can be, for example, Al₂O₃, TiO₂, ZrO₂, HfO₂, SrTiO₃ (STO) or BaSrTiO₃ (BST) or ZrO₂ stabilized by Y. The electrodes are manufactured by atomic layer deposition (ALD) which is the only approach that has been able to achieve perfect compliance on a complex shape structure, such as the U-shape. The ALD method is also the only one that has been able to obtain thin upper electrodes. However, these methods reach limits at technological nodes of 100 nm. In addition, they must be optimized to increase capacitance density, to perfectly fill cavities and to limit current leakage.

In other semiconductor devices, such as three-dimensional integrated circuits, the metal interconnects connecting the electronic components contain copper, which is separated from the semiconductor substrate by layers of barrier materials such as titanium nitride and tantalum nitride to prevent the diffusion of copper into the semiconductor substrate. It would be desirable to remove barrier layers to improve the performance of such devices.

It has already been proposed in WO2021/219744 to deposit an alloy of nickel and boron on a metal oxide autocatalytically. However, this nickel alloy deposit does not produce a conductive deposit at thin thicknesses and it would be desirable to improve this technology to deposit alloy layers that remain conductive (i.e., exhibit a resistivity of less than about 0.1 ohm·cm at very thin thicknesses (i.e., thicknesses of less than 50 nm).

There remains a need in the art for a metallization process that can be used to manufacture storage memories or integrated circuits, which allows for the deposit of thin conductive layers on substrates, such as a mineral oxide substrates.

### SUMMARY OF THE INVENTION

It is an object of the present invention to provide a method of metallizing a mineral oxide substrate with an nickel or cobalt alloy comprising at least two elements.

It is another object of the present invention to provide a method of metallizing a mineral oxide substrate by electroless plating of a nickel or cobalt alloy layer on a surface of the mineral oxide substrate.

It is still another object of the present invention to provide a method of electroless deposition of a nickel or cobalt oxide layer on the metal oxide layer that produces a conductive deposit at very thin thicknesses.

The method of the invention meets this need by providing a method for electroless plating of a nickel or cobalt alloy on a mineral oxide substrate to allow the deposition of a nickel or cobalt alloy comprising boron and at least one of phosphorus and tungsten on the surface of the mineral oxide substrate.

### DETAILED DESCRIPTION

In one embodiment, the present invention relates generally to a method of metallizing at least a surface of a mineral oxide substrate by electroless plating of a nickel or cobalt alloy comprising at least two elements, the first element being boron and the second element being selected from phosphorus and tungsten. The metallization process comprises a step of activating a surface of the mineral oxide substrate with a noble metal followed by a step of contacting said surface with an electroless aqueous solution comprising nickel (or cobalt) ions, a reducing agent of nickel (or cobalt) ions containing boron, and a compound containing at least one of phosphorus or tungsten.

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath,” “below,” “lower,” “above,” “upper” and the like, are used for ease of description to describe one element or feature' s relationship to another element(s) or feature(s) as illustrated in the figures. It is further understood that the terms “front” and “back” are not intended to be limiting and are intended to be interchangeable where appropriate.

As used herein, the terms “comprises” and/or “comprising,” specify the presence of stated features, integers, steps, operations, elements, and/or components, but do not preclude the presence or addition of one or more other features, integers, steps, operations, elements, components, and/or groups thereof.

As used herein, the term “substantially free” or “essentially free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically techniques.

All amounts are percent by weight unless otherwise noted. All numerical ranges are inclusive and combinable in any order except where it is logical that such numerical ranges are constrained to add up to 100%.

The terms “composition” and “bath” and “solution” are used interchangeably throughout this specification.

As used herein, the term “alloy” means a solid solution in which the elements are evenly distributed.

In one embodiment, the alloy is a nickel alloy comprising boron and at least one of phosphorus and tungsten.

In another embodiment, the alloy is a cobalt alloy comprising boron and at least one of phosphorus and tungsten.

The reducing agent of nickel or cobalt ions comprising boron is preferably in sufficient quantity so that boron represents between 1 at % and 10 at % in the nickel alloy.

According to one embodiment, the nickel alloy deposited by the method of the invention is a nickel alloy containing boron and phosphorus. Boron preferably represents between 0.1 at. % and 10 at. % of the nickel alloy, more preferably between 0.1 and 5.0 at. %, more preferably between 0.1 and 3.0 at. %, and phosphorus preferably represents between 0.1 at. % and 10 at. % of the nickel alloy, more preferably between 0.1 and 5.0 at. %, more preferably between 0.1 and 3.0 at. %. The presence of both boron and phosphorus in the alloy at the recited at. % produces a deposit that is more conductive especially at very low thicknesses, such as thicknesses of less than about 50 nm, and in which the deposit does not exhibit any pinholes or voids.

According to another embodiment, the nickel alloy obtained by the method described herein is a nickel alloy containing boron and tungsten. Boron preferably represents between 0.1 at. % and 10 at. % of the nickel alloy, more preferably between 0.1 and 5.0 at. %, more preferably between 0.1 and 3.0 at. %, and tungsten preferably represents between 1% and 10% atomic of the nickel alloy, more preferably between 2.0 and 8.0 at. %. The presence of both boron and tungsten in the alloy at the recited at. % produces a deposit that is more conductive, especially at very low thicknesses, such as thicknesses of less than about 50 nm, and in which the deposit does not exhibit any pinholes or voids.

According to another embodiment, the alloy obtained by the method described herein is a cobalt alloy containing boron and phosphorus. Boron preferably represents between 0.1 at. % and 10 at. % of the cobalt alloy, more preferably between 0.1 and 5.0 at. %, more preferably between 0.1 and 3.0 at. %, and phosphorus preferably represents between 0.1% and 10% atomic of the cobalt alloy, more preferably between 0.1 and 5.0 at. %, more preferably between 0.1 and 3.0 at. %. The presence of both boron and phosphorus in the alloy at the recited at. % produces a deposit that is more conductive, especially at very low thicknesses, such as thicknesses of less than about 50 nm, and in which the deposit does not exhibit any pinholes or voids.

According to another embodiment, the alloy obtained by the method described herein is a cobalt alloy containing boron and tungsten. Boron preferably represents between 0.1 at. % and 10 at. % of the cobalt alloy, more preferably between 0.1 and 5.0 at. %, more preferably between 0.1 and 3.0 at. %, and tungsten preferably represents between 1.0 at. % and 10 at. % of the cobalt alloy, more preferably between 2.0 and 8.0 at. %. The presence of both boron and tungsten in the alloy at the recited at % produces a deposit that is more conductive, especially at very low thicknesses, such as thicknesses of less than about 50 nm, and in which the deposit does not exhibit any pinholes or voids.

In one embodiment, the dielectric substrate such as a mineral oxide substrate is activated with an activation solution containing a noble metal complex. In one embodiment, the noble metal of the noble metal complex is palladium. Other noble metals that can be used in activation solution to activate the mineral oxide surface include ruthenium, rhodium, osmium, iridium, platinum, gold, silver, and combinations of one or more of the foregoing.

The present application describes an electroless nickel or cobalt bath, which can be used in particular for the implementation of the method described above, comprising:
a. nickel or cobalt ions in a concentration, for example, between 10⁻² M and 1 M;
b. a reducing agent for the nickel or cobalt ions containing boron in a concentration which may be between 10⁻¹ M and 1 M;
c. at least one of a compound containing phosphorus or a compound containing tungsten; and
d. an agent for adjusting the pH to a value between 6 and 11, preferably between 8 and 10.

The phosphorus-containing compound is preferably in a concentration between 10⁻¹ M and 1 M, preferably between 0.1 M and 0.5 M. The tungsten-containing compound is preferably in a concentration between 0.3 mM and 30 mM, preferably between 1 mM and 5 mM.

The invention also relates to a three-dimensional semiconductor device obtainable by implementing the method described above.

The method of the invention is applied in particular in the realization of the filling of cavities which have been previously formed in a semiconductor substrate, and whose dimension at their opening is less than 5 microns, or less than 3 microns or less than 1 micron or less than 500 nm or less than 100 nm or less than 50 nm or less than 25 nm or less than 10 nm.

The method of the invention makes it possible to create metal deposits on substrates with complex topographies in terms of relief and shape, and to create metal layers on the walls of cavities of small size at their opening as defined above and depths of up to 50 microns or up to 100 microns or up to 200 microns. The method of the invention makes it possible in particular to overcome the problem of diffusion of copper into the layers of barrier material.

The contact of the electroless solution with the mineral oxide surface is carried out for example under conditions allowing the formation of a nickel (or cobalt) alloy layer having a thickness of between about 1 and about 25 nm, more preferably between about 2 and about 20 nm, more preferably at least about 4 to about 15 nm, more preferably a thickness of about 5 nm to 10 nm, which nickel or cobalt alloy layer is at least substantially free of pinholes and other defects. The average resistivity of this nickel (or cobalt) alloy layer, measured by means of a four-point probe at several locations on the plated nickel or cobalt ally surface. The average resistivity may be in the range of about 30 to 60 μohm cm as measured at 10-40 nm. The resistivity of the alloy layer is preferably less than 55 μohm cm when the layer thickness is less than or equal to 10 nm.

The mineral oxide substrate may be selected from silicon dioxide (SiO₂), alumina (Al₂O₃), hafnium oxide, zirconium oxide and their silicates, by way of example and not limitation.

In a particular embodiment, a nickel or cobalt alloy layer obtained by the method of the invention has the same or better conductivity as a metal layer obtained according to the teaching of FR 3 109 840, but is characterized by a lower thickness. In particular, the thickness of the nickel or cobalt alloy in accordance with the present invention may be less than 50 nm or less than 40 nm or less than 30 nm or less than 20 nm or less than 10 nm with at least substantially no defects such as pinholes or voids.

The conductivity of a nickel alloy layer obtained in accordance with the teachings of the present invention is generally in the range of about 30 to about ohm cm at a thickness of about 10 to about 40 nm.

The conductivity of a cobalt alloy layer obtained in accordance with the teachings of the present invention is generally in the range of about 35-45 ohm cm at a thickness of about 30 nm.

The activation of the surface can be carried out for example by grafting a noble metal such as palladium according to the teachings of WO2011/029860 or U.S. Pat. No. 8,883,641. Other noble metals include ruthenium, rhodium, osmium, iridium, platinum, gold, and silver or combinations thereof. The activation of the surface of the insulating layer can also be carried out by deposition of nanoparticles of a metal, such as nickel-boron nanoparticles as described in WO 2010/001054.

According to one embodiment, when the dielectric is a mineral oxide, and in particular SiO₂ or Al₂O₃, the activation of the surface is carried out with an activation solution containing a solvent, at least one noble metal complex which noble metal complex may be a ruthenium, rhodium, osmium, iridium, palladium platinum, gold, and/or silver complex and at least one organo-silane compound. In one embodiment, the activation solution comprises a solvent, a palladium complex and at least one organo-silane compound.

The palladium complex may be selected from (NH₄)₂(PdCl₄); Pd(NH₃)₄ and complexes of formula (I):

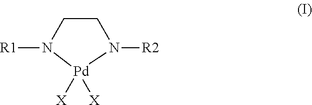

wherein:
R1 and R2 are identical and represent H; CH₂CH₂NH₂; or CH₂CH₂OH; or
R1 represents H and R2 represents CH₂CH₂NH₂; or
R1 represents CH₂CH₂NH₂ and R2 represents CH₂CH₂NHCH₂CH₂NH₂; or
R1 represents H and R2 represents CH₂CH₂NHCH₂CH₂NHCH₂CH₂NH₂; and
X represents a ligand selected from the group consisting of Cl⁻; Br⁻; I⁻; H₂O, NO₃⁻; CH₃SO₃⁻; CF₃SO₃⁻; CH₃⁻ Ph-SO₃⁻; or CH₃COO⁻.

In one embodiment, the activation solution comprises the palladium complex or complexes in a concentration of 10⁻⁶ M to 10⁻² M, preferably from 10⁻⁵ M to 10⁻³ M, preferably from 5·10⁻⁵ M to 5·10⁻⁴ M.

The organo-silane compound within the activation solution ensures adhesion between the nickel or cobalt alloy layer and the mineral oxide.

According to a particular feature of the invention, the organo-silane compound has the general formula (II):

{X-(L)}₃₋ₙSi(OR)ₙ (II)

wherein:
X represents a functional group selected from the group consisting of thiol, pyridyl, epoxy (oxacyclopropanyl), glycidyl, and primary amines capable of reacting with simple palladium compounds or formula (I);
L represents a spacer arm selected from the group consisting of CH₂; CH₂CH₂; CH₂CH₂CH₂; CH₂CH₂CH₂CH₂—; CH₂CH₂NHCH₂CH₂; CH₂CH₂CH₂NHCH₂CH₂; CH₂CH₂CH₂NHCH₂CH₂NHCH₂CH₂; CH₂CH₂CH₂NHCH₂CH₂CH₂CH₂CH₂CH₂CH₂; Ph; Ph-CH₂; and CH₂CH₂-Ph-CH₂; (Ph representing a phenyl ring)
R is a group selected from the group consisting of CH₃, CH₃CH₂, CH₃CH₂CH₂, and (CH₃)₂CH; and
n is an integer equal to 2 or 3.

The organo-silane compound may also have the general formula (III):

(OR)₃Si-(L)-Si(OR)₃ (III)

wherein:
L represents a spacer arm selected from the group consisting of CH₂CH₂CH₂ NHCH₂CH₂NHCH₂CH₂ and CH₂CH₂CH₂—S—S—CH₂CH₂CH₂, and
R is a group selected from the group consisting of CH₃, CH₃CH₂, CH₃CH₂CH₂, and (CH₃)₂CH.

Compounds of general formulas (II) or (III) may be selected from the following compounds: (3-Aminopropyl) triethoxysilane; (3-Aminopropyl)trimethoxysilane; m-Aminophenyltrimethoxysilane; p-Aminophenyltrimethoxysilane; p,m-aminophenyltrimethoxysilane; 4-Aminobutyltriethoxysilane; m, p (Aminoethylaminomethyl)phenethyltrimethoxysilane; N-(2-aminoethyl)-3-aminopropyltriethoxysilane; N-(2-aminoethyl)-3-aminopropyltrimethoxysilane; 2-(4-Pyridylethyl)triethoxysilane; Bis (3-trimethoxysilylpropyl)ethylenediamine; (3-Trimethoxysilylpropyl)diethylenetriamine; Ethylenediamine, N-(3-Trimethoxysilyethyl)ethylenediamine; N-(6-aminohexyl)aminopropyltrimethoxysilane; (3-Glycidoxypropyl)trimethoxysilane; (3-Glycidoxypropyl)triethoxysilane; 5,6-Epoxyhexyltriethoxysilane; (3-Mercaptopropyl)trimethoxysilane; (3-Mercaptopropyl)triethoxysilane; Bis [3-(triethoxysilyl)propyl]disulfide; 3-Chloropropyltrimethoxys ilane; 3-Chloropropyltriethoxysilane; (p-chloromethyl)phenyltrimethoxysilane; and m,p ((Chloromethyl)phenylethyl)trimethoxysilane.

Examples of preferred organo-silane compounds that may be used in the practice of the present invention include compounds of formula (II) wherein:
X represents an NH₂ group and L represents CH₂CH₂CH₂— and R represents CH₃ (i.e., (3-aminopropyl)-trimethoxy-silane or APTMS); OR L represents CH₂CH₂CH₂ and R represents CH₃CH₂ (i.e., (3-aminopropyl)-triethoxy-silane or APTES); OR L represents CH₂CH₂NHCH₂CH₂ and R represents CH₃ (i.e., [3-(2-aminoethyl)aminopropyl]trimethoxy-silane or DATMS or DAMO); OR
X represents SH; and L represents CH₂CH₂CH₂— and R represents CH₂CH₃ (i.e., (3-Mercaptopropyl) trimethoxysilane or MPTES); OR
X represents C₆H₅N; L represents CH₂CH₂- and R represents CH₂CH₃ (i.e., 2-(4-Pyridylethyl) triethoxysilane or PETES); OR
X represents CHCH₂O; L represents CH₂CH₂CH₂ and R represents CH₃ (i.e., (3-Glycidoxypropyl) trimethoxysilane or EPTMS). or X represents Cl; L represents CH₂CH₂CH₂ and R represents CH₃ (i.e., 3-Chloropropyltrimethoxysilane or CPTMS).

In one embodiment, the organo-silane compound is (3-aminopropyl)-trimethoxy-silane (APTMS).

The concentration of the organo-silane compound in the activation solution is preferably between 10⁻⁵ M and 10⁻¹ M, preferably between 10⁻⁴ M and 10⁻² M, preferably between 5·10⁻⁴M and 5·10⁻³ M.

The solvent of the activation solution must be capable of solubilizing the compounds contained in the activation solution. This solvent system may consist of one or more solvents selected (s) from the group consisting of N-methylpyrrolidinone (NMP), dimethyl sulfoxide (DMSO), alcohols, ethylene glycol ethers such as monoethyl-diethylene glycol (EDEG), propylene glycol ethers, dioxane and toluene. In general, the solvent system is advantageously consisting of a mixture of a solvent capable of solubilizing palladium compounds in combination with a solvent such as ethylene glycol ether or propylene glycol ether. In one embodiment, a particularly preferred solvent system because of its very low toxicity, consists of dimethyl sulfoxide (DMSO) alone or a mixture of dimethyl sulfoxide (DMSO) and monoethyl ether diethylene glycol (EDEG). These compounds can be used in a volume ratio between 1:200 and 1:5, preferably about 1:10.

In one embodiment, the activation solution for activating the mineral oxide surface is a palladium complex with ethylenediamine and aminopropyl trimethoxy-silane (APTMS).

Once the mineral oxide surface has been activated with the activation solution, the activated mineral oxide surface can be contacted with an electroless metal alloy plating solution as further defined herein.

In the case of an electroless nickel solution, the nickel ions are introduced into the electroless solution by dissolving a nickel metal salt. In one embodiment, the nickel salt is selected from the group consisting of acetate, acetylacetonate, hexafluorophosphate, nitrate, perchlorate, sulfate or nickel tetrafluoroborate. A hydrated form of one of the listed nickel salts may also be used. In one embodiment, the salt is nickel sulfate hexahydrate. The nickel ions are in a concentration for example between 10⁻² M and 1 M, preferably between 50 mM and 500 mM.

In the case of an electroless cobalt solution, the cobalt ions are introduced into the electroless solution as an inorganic cobalt salt such as chloride and/or sulfate or other inorganic salts or inorganic complexes such as pyrophosphates or a cobalt complex with an organic carboxylic acid salt such as acetate, citrate, lactate, succinate, propionate, and hydroxyacetate. The cobalt ions are in a concentration for example between 10⁻² M and 1 M, preferably between 50 mM and 500 mM.

The reducing agent comprising boron may be a borane derivative such as a borane derivative selected from dimethylaminoborane, pyridine borane, morpholene borane and terbutylamine borane.

The compound containing phosphorus as a doping element may be hypophosphorous acid or one of its salts, for example sodium hypophosphite or magnesium hypophosphite. The compound comprising phosphorus as a doping element is for example in a concentration between 10 mM and 1 M, preferably between 400 mM and 600 mM.

The compound containing tungsten as a doping element may be a tungstate salt such as for example sodium tungstate, calcium tungstate or ammonium tungstate. The compound comprising tungsten as a doping element is for example in a concentration between 0.3 mM and 30 mM, preferably between 1 mM and 5 mM.

The electroless solution optionally contains at least one nickel ion or cobalt alloy stabilizing agent, preferably in an amount between 10⁻³ M and 1 M, more preferably in an amount between about 0.1 M and 1 M.

The optional nickel or cobalt ion stabilizing agent may be selected from the group consisting of ethylene diamine, citric acid, acetic acid, succinic acid, malonic acid, aminoacetic acid, malic acid or an alkali metal salt of these compounds. In one embodiment, the nickel or cobalt ion stabilizing agent comprises citric acid, which forms complexes with nickel or cobalt ions in the solution.

The aqueous electroless solution may also comprise a pH adjusting agent for adjusting the pH to a value between 6 and 11. In one embodiment, the pH of the aqueous solution is in the range of 8 to 10, more preferably between 9.0 and 9.5. The pH adjusting agent may be selected from the group consisting of aminoethanol, N-methyl aminoethanol and N, N-dimethyl-aminoethanol. A preferred pH adjusting agent is N-methyl aminoethanol.

The electroless plating solution may also contain a polyamine, preferably an aliphatic polyamine, in a concentration that may be between 5 ppm and 1000 ppm (mg/L), more preferably between about 10 and about 100 ppm.

In a preferred embodiment, the electroless solution contains a polyamine, preferably a polyethyleneimine, and preferably a polyethyleneimine having a molecular weight greater than or equal to 500 g/mol, more preferably greater than about 600 g/mol, more preferably greater than about 700 g/mol.

The solution may alternatively contain a polymer selected from derivatives of chitosan, poly (allyl-amine), poly (vinyl-amine), poly (vinyl-pyridine), poly (amino-styrene), poly (L-lysine), and acid (or protonated) forms of these polymers.

The contact of the substrate with the electroless solution can be carried out by immersing the mineral oxide substrate in the solution described above, at a temperature between 40° C. and 90° C., preferably at 60° C. to 70° C., for a period of 30 seconds to 15 minutes, more preferably about 1 to about 10 minutes, depending on the desired thickness of nickel alloy. The contact of the electroless solution is advantageously carried out for a sufficient time to obtain a nickel or cobalt alloy layer having a thickness of greater than 1 nm to less than 25 nm, more preferably greater than or equal to 4 nm to less than or equal to 10 nm.

The deposition step of the alloy metal layer can be carried out under different process conditions. For example, in one embodiment, the substrate to be coated can be rotated. In another embodiment, a recirculation of the electroless solution can be imposed in the reactor. In another embodiment, contact of the substrate with the electroless solution can be carried out by spraying the solution at high pressure. Other means can also be used in a complementary way, for example, by shaking the substrate and/or the solution with ultrasound or megasound. In all cases, the contact can be carried out under vacuum. The surface to be coated can be positioned face up or face down.

According to an advantageous embodiment, this electroless nickel or cobalt alloy layer can be annealed at a temperature between 200° C. and 700° C., preferably between 350° C. and 450° C., for a period of between 1 minute and 30 minutes, preferably about 5 minutes to about 15 minutes, more preferably about 10 minutes, under an inert or reducing atmosphere (e.g., 4% hydrogen in nitrogen).

This application describes an electroless solution comprising:
a) between 10² M and 1 M, preferably between 50 mM and 500 mM of nickel or cobalt ions;
b) between 101 M and 1 M, preferably between 400 mM and 600 mM, of at least one reducing agent containing boron;
c) between 10⁻¹ M and 1 M, preferably between 400 mM and 600 mM, of a compound containing phosphorus, preferably hypophosphorous acid or a salt, or between 0.3 mM and 30 mM of a tungsten-containing compound, preferably a tungstate salt;
d) optionally, one or more nickel or cobalt ion stabilizing agents;
d) optionally, a pH adjuster;
e) between 5 mg/L and 1000 mg/L (or ppm) of an amino polymer, preferably a polyethyleneimine, more preferably wherein the polyethyleneimine has a molecular weight in the range of 500 to 25,000 g/mol, more preferably about 600 to about 20,000 g/mol, more preferably about 700 to about 15,000 g/mol, more preferably about 800 to about 10.000 g/mole, more preferably about 1,000 to about 5,000 g/mol; and
balance water.

In one embodiment, the electroless solution consists essentially of the listed ingredients. What is meant by “consisting essentially of” is that the electroless solution is free of any ingredients that would have a detrimental effect on conductivity, including a concentration of boron, phosphorus, and/or tungsten in excess of the ranges defined herein.

In one embodiment, the electroless solution consists of the listed ingredients to provide an electroless nickel or cobalt alloy layer on a mineral oxide substrate that exhibits good conductivity at very low thicknesses.

The molar ratio between boron and phosphorus in the electroless solution is preferably between 1/10 and 10/1, more preferably between 1/5 and 5/1, more preferably between 1/2 and 2/1.

The molar ratio between boron and tungsten in the electroless solution is preferably between 10/1 and 500/1, preferably between 50/1 and 300/1, preferably between 100/1 and 200/1.

The metallization method of the invention can be used for the manufacture of three-dimensional semiconductor devices, such as three-dimensional integrated circuits or 3D-NAND type storage memories, at the level of creating copper conductive lines, or such as V-DRAM storage memories or MIM capacitors forming part of the structure of DRAM storage memories.

The present invention also relates generally to a semiconductor device obtainable by implementing the method or electrolyte described above.

The present application also describes a three-dimensional semiconductor device comprising a thin layer of an alloy of nickel, boron and phosphorus comprising from 1% to 10% atomic, preferably from 1% to 7% atomic, boron and from 1% to 10% atomic, preferably from 1% to 7% atomic phosphorus deposited on a mineral oxide surface.

The present application further describes a three-dimensional semiconductor device comprising a thin layer of an alloy of nickel, boron and tungsten comprising from 1% to 10% atomic, preferably from 1% to 7% atomic, boron and from 1% to 10% atomic, preferably from 1% to 7% atomic tungsten deposited on a mineral oxide surface. The metallization method of the invention can thus be used for the manufacture of copper conductive lines comprising a step of depositing a nickel alloy layer on the walls of mineral oxide cavities, which cavities are intended to be filled with copper in subsequent processing steps.

The present application also describes a three-dimensional semiconductor device comprising a thin layer of an alloy of cobalt, boron and phosphorus comprising from 1% to 10% atomic, preferably from 1% to 7% atomic, boron and from 1% to 10% atomic, preferably from 1% to 7% atomic phosphorus deposited on a mineral oxide surface.

The present application further describes a three-dimensional semiconductor device comprising a thin layer of an alloy of cobalt, boron and tungsten comprising from 1% to 10% atomic, preferably from 1% to 7% atomic, boron and from 1% to 10% atomic, preferably from 1% to 7% atomic tungsten deposited on a mineral oxide surface. The metallization method of the invention can thus be used for the manufacture of copper conductive lines comprising a step of depositing a cobalt alloy layer on the walls of mineral oxide cavities, which cavities are intended to be filled with copper in subsequent processing steps.

These cavities may have, for example, an average diameter at the opening ranging from 10 nm to 30 nm and a depth ranging from 20 nm to 100 nm. The average diameter at the opening of the cavities is preferably less than 500 nm, for example less than 400 nm or less than 300 nm or less than 200 nm or less than 100 nm or less than 50 nm or less than 10 nm.

The invention is illustrated by reference to the following non-limiting examples.

### Example 1: Deposition of a Thin Layer of Nickel-Boron-Phosphorus Alloy on the Walls of Cavities

In this example, the substrate used is a SiO₂ coupon of 4 cm×4 cm side and 750 μm thick, having vertical cavities with an aperture of about 10 m and height of about 100 micrometers.

### (a) Cleaning of the Surface of Cavities:

The coupon is cleaned according to the chemical nature of the substrate. After this cleaning step, the coupon is rinsed thoroughly with deionized water, immersed in a beaker filled with deionized water subjected to ultrasound (40 kHz) for 2 minutes.

### b) Activation of the Cavity Surface:b1) Preparation of the Activation Solution:

In a beaker, 350 microliters of (3-aminopropyl)-trimethoxy-silane (APTMS) and 15 mg of Pd (ethylenediamine) Cl₂ are dissolved in 80 ml of dry DMSO (maximum 50 ppm or mg/L H2O).

### (b2) Substrate Surface Activation Treatment:

The coupon prepared in step al) is immersed in the beaker comprising the activation solution prepared in b1) at a temperature of 65° C. and under ultrasound for 15 minutes. The coupon is removed from the solution, rinsed thoroughly with deionized water, immersed in a beaker filled with deionized water subjected to ultrasound (40 kHz) for 30 seconds. The coupon is finally removed from the beaker, rinsed thoroughly with deionized water.

### C) Deposition of a Layer of Metal NiB by Electroless Plating:

c1) Preliminary preparation of the electroless solution:
In a container of 1 liter and a minimum of deionized water are introduced in order, 31.11 g of nickel sulfate hexahydrate (0.118 moles), 44.67 g of citric acid (0.232 moles), 52.26 g of N-methyl aminoethanol (0.700 moles), 25 ppm of polyethyleneimine (PEI) with Mn=600 g/mol, 6 ml of hypophosphorous acid 50% (0.475 moles). The final pH was adjusted to 9.3 with N-methyl-aminoethanol and the total volume was adjusted to 1 liter with deionized water. To nine volumes of the previous solution, just before the next step, a volume of a reducing solution is added. The latter comprises 28 g/L of dimethyl-amino borane (DMAB; 0.475 moles) and 60.00 g of N-methyl aminoethanol (0.798 moles).

### c2) Formation of the NiB Alloy Layer on the Alumina Layer:

A nickel-boron alloy layer was deposited on the surface of the substrate treated in step b) by first immersing it in a beaker of deionized water and then soaking it in the electroless solution previously prepared and heated to 65° C., for a period of 2 minutes. A gray and shiny metal cover is then observable on the coupon. The coupon is removed from the solution, rinsed thoroughly with deionized water, immersed in a beaker filled with deionized water subjected to ultrasound (40 kHz) for 30 seconds. The coupon is finally removed from the beaker, rinsed thoroughly with deionized water and dried under a stream of nitrogen. The coupon is subject to Rapid Thermal Annealing (RTA) at 400° C. for ten minutes in a reducing atmosphere (4% hydrogen in nitrogen). The operation can be performed with a tubular oven or a hot plate.

### (d) Properties of the Metal Deposit Filling the Cavities

The vertical cavities are covered with a thin layer of nickel alloy containing boron and phosphorus. The thickness of the nickel layer, measured under a microscope at a magnification of 150,000, ranges from 7 nm to 10 nm over the entire sample. Conductivity, measured using a four-point probe at different points in the sample, ranged from 35 to 60 ohm·cm.

### Comparative Example 2

Example 1 was reproduced with the difference that, in step c1), the concentration of hypophosphorous acid was reduced to 0.0475 mole and the concentration of PEI was reduced to 2.5 ppm.

It is observed that the walls of the vertical cavities are covered with a thin layer of the nickel-boron alloy comprising less than 1% atomic phosphorus and whose thickness, measured under a microscope at a magnification of 150,000, ranges from 7 nm to 10 nm. The resistivity ranged from 65 to 120 ohm·cm. The nickel alloy deposit obtained is more resistive, less dense, less compact and has more defects than the deposit obtained in Example 1 with the method of the invention. This example demonstrates that while trace amounts of phosphorus in the electroless nickel plating bath may produce a nickel deposit, the resulting nickel deposit does not exhibit good properties at the desired thicknesses of the instant invention. Likewise, this examples also shows that the use of PEI at a concentration with the range described by the invention also aids in producing an electroless nickel deposit exhibiting the desired properties.

### Example 3: Deposition of a Thin Layer of Nickel-Boron-Tungsten Alloy

Example 1 was reproduced with the difference that, in step c1), the 0.475 moles of hypophosphorous acid were replaced by 3 mM of sodium tungstate dihydrate. The vertical cavities are covered with a continuous layer of nickel alloy containing boron and tungsten, which is dense and compact with a resistivity equal to 30 ohm·cm, thereby improving conductivity by 25% when the layer thickness is less than 10 nm.

1. A process for metallizing at least a surface of a mineral oxide substrate with a nickel or cobalt alloy comprising at least two elements, the first element being boron and the second element being selected from phosphorus and tungsten, said metallization process comprising the steps of:
a) activating the surface of the mineral oxide substrate with a noble metal activation solution, and thereafter
b) contacting said surface of the mineral oxide substrate with an electroless nickel or cobalt solution to form the nickel or cobalt alloy, the electroless nickel or cobalt solution comprising:
i) nickel or cobalt ions,
ii) a nickel or cobalt ion reducing agent comprising boron, and
iii) a compound comprising a doping element selected from phosphorus and tungsten,
wherein the compound comprising the doping element is in a sufficient amount so that the dopant element represents between 1% and 10% atomic of the nickel or cobalt alloy.

2. The process according to claim 1, wherein the molar ratio between boron and phosphorus in the electroless nickel or cobalt solution is between 1/10 and 10/1.

3. The process according to claim 1, wherein the molar ratio between boron and tungsten in the electroless nickel or cobalt solution is between 10/1 and 500/1.

4. The process according to claim 1, wherein the nickel or cobalt ions are in a concentration between 10⁻² M and 1 M.

5. The process according to claim 1, wherein the compound comprising phosphorus as a doping element is in a concentration between 400 mM and 600 mM.

6. The process according to claim 1, wherein the compound comprising phosphorus as a doping element is selected from hypophosphorous acid and its salts.

7. The process according to claim 6, wherein the compound comprising phosphorus as a doping element is selected from the group consisting of hypophosphorous acid, sodium hypophosphite, and magnesium hypophosphite.

8. The process according to claim 1, wherein the compound comprising tungsten as a doping element is in a concentration between 0.3 mM and 30 mM.

9. The process according to claim 1, wherein the compound comprising tungsten as a doping element is a tungstate salt.

10. The process according to claim 9, wherein the tungstate salt is selected from the group consisting of sodium tungstate, calcium tungstate, and ammonium tungstate.

11. The process according to claim 1, wherein the contact of the electroless nickel or cobalt solution is carried out for a sufficient time to obtain a nickel or cobalt alloy layer having a thickness less than or equal to 10 nm.

12. The process according to claim 1, wherein the reducing agent of nickel or cobalt ions comprising boron is in sufficient quantity so that boron represents between 1 at % and 10 at % in the nickel or cobalt alloy.

13. The process according claim 1, wherein the nickel or cobalt ion reducing agent is dimethylaminoborane.

14. The process according to claim 1, characterized in that the mineral oxide substrate is SiO₂ or Al₂O₃.

15. The process according to claim 1, wherein a noble metal contained in the noble metal activation solution is palladium.

16. The process according to claim 15, wherein the noble metal activation solution comprises a solvent, a palladium complex and an organo-silane compound.

17. The process according to claim 1, wherein the electroless nickel or cobalt solution comprises a pH adjusting agent for adjusting the pH to a value between 6 and 11.

18. The process according to claim 1, wherein the electroless nickel or cobalt solution comprises between 5 ppm and 1,000 ppm of a polyamine.

19. The process according to claim 1 further comprising a step of rapid thermal annealing of the nickel or cobalt alloy layer formed on the surface of the mineral oxide substrate.

20. A three-dimensional semiconductor device obtained by the process according claim 1.

21. A process for metallizing at least a surface of a mineral oxide substrate with a nickel or cobalt alloy comprising at least two elements, the first element being boron and the second element being selected from phosphorus and tungsten, said metallization process comprising the steps of:
a) activating the surface of the mineral oxide substrate with a noble metal activation solution, and thereafter
b) contacting said surface of the mineral oxide substrate with an electroless nickel or cobalt solution to form the nickel or cobalt alloy, the electroless nickel or cobalt solution consists essentially of:
i) nickel or cobalt ions;
ii) a nickel or cobalt ion reducing agent comprising boron; and
iii) a compound comprising a doping element selected from phosphorus and tungsten,
wherein the compound comprising the doping element is in a sufficient amount so that the dopant element represents between 1% and 10% atomic of the nickel or cobalt alloy.
